(19) United States
(12) Patent Application Publication
(10) Pub. No.: US 2026/0204168 A1
(43) Pub. Date: Jul. 16, 2026

(54) COMPUTER-IMPLEMENTED METHOD FOR REPAIRING AN AGRICULTURAL MACHINE

(71) Applicant: CLAAS E-Systems GmbH, Dissen am Teutoburger Wald (DE)

(72) Inventors: Benjamin JATHE, Steinhagen (DE); Ralf ITZEK, Beelen (DE); Reinhard HESSE, Versmold (DE); Jörn GRUNWALD, Marienfeld (DE); Martin PELLENGAHR, Münster (DE); Stephan NIEWÖHNER, Münster (DE); Sebastian RÜTER, Harsewinkel (DE)

(21) Appl. No.: 19/445,127

(22) Filed: Jan. 9, 2026

(30) Foreign Application Priority Data
Jan. 15, 2025 (DE) 10 2025 101 263.6

(51) Int. Cl. G09B 5/06; A01B 76/00; A01D 41/127; G06F 30/20; G07C 5/08

(52) U.S. Cl. CPC G09B 5/06; G06F 30/20; G07C 5/0808; G07C 5/0841; A01B 76/00; A01D 41/127

(57) ABSTRACT

The present invention relates to a computer-implemented method for repairing an agricultural machine, wherein the agricultural machine comprises a component to be maintained, the method comprising: providing a computer-aided model, wherein the computer-aided model is assigned to the component to be maintained; recording an actual condition of the component to be maintained and adjusting the computer-aided model to the recorded actual condition of the component (205) to be maintained; determining repair scenarios for the agricultural machine based on the computer-aided model; and ascertaining a repair measure using the repair scenarios.

### CROSS-REFERENCE TO RELATED APPLICATIONS

This application claims priority to German Patent Application No. 10 2025 101 263.6 (filed on Jan. 15, 2025) which is incorporated by reference in its entirety.

### FIELD OF THE INVENTION

The present invention relates to a computer-implemented method for repairing an agricultural machine. Furthermore, the present invention relates to a method for performing a guided repair of a component to be maintained based on an ascertained repair measure. The present invention also relates to a data processing system for repairs to an agricultural machine and an agricultural repair assistant.

### BACKGROUND OF THE INVENTION

Methods for repairing agricultural machinery are known from the prior art.

EP 3738421 B1 proposes a method for this purpose in which an analysis routine ascertains the probability of failure or damage to the agricultural machine or a component of the agricultural machine on the basis of operating data. A delivery routine can be initiated based on the analysis routine.

After delivery of the replacement part, it is usually necessary to initiate repair measures at the service point. Given the increasing number and complexity of components, as well as the tools required for repairs, this work is becoming increasingly demanding. Therefore, there is a need for improved methods that are more cost-effective, efficient, and compact.

The present invention aims to develop a method for repairing agricultural machinery that enables quick and reliable maintenance.

This task is solved by the embodiments disclosed herein, which are defined in particular by the subject matter of the independent claims. The dependent claims relate to further embodiments. Various aspects and embodiments of these aspects are also disclosed in the following summary and description, which provide additional features and benefits.

### SUMMARY OF THE INVENTION

One aspect relates to a computer-implemented method for repairing an agricultural machine. The agricultural machine may comprise a component to be maintained. The method may comprise, in one step, providing a computer-aided model, wherein the computer-aided model may be associated with the component to be maintained. In a further step, the method may include recording the actual condition of the component to be maintained. Furthermore, the method may include adjusting the computer-aided model to the recorded actual condition of the component to be maintained. In addition, the method may comprise, in a further step, determining repair scenarios for the agricultural machine based on the computer-aided model. In a further step, the method may include ascertaining a repair measure using the repair scenarios.

The agricultural machine may be specifically designed for harvesting crops. Agricultural machinery can include, for example, a forage harvester, combine harvester, or tractor. The agricultural machine may be self-propelled and/or autonomous. Repairing agricultural machinery can refer to the process of restoring agricultural machinery that is defective or not functioning optimally to at least a partially operational and efficient condition.

The component to be maintained may refer to a specific element or component of the agricultural machine that requires (regular) inspection, care, or repair (i.e., maintenance) in order to maintain its functionality and performance. In an agricultural context, this could be, for example, a part of a tractor or harvester that requires attention due to wear, aging, or damage. For the present method, it may already be known which component is to be maintained. This means that it does not need to be identified, but rather it may already have been determined prior to the method or be generally known which component is to be maintained.

The provision of the computer-aided model may refer to the process of creating and making available a digital representation or simulation of a physical object, system, or process. The computer-aided model is developed using computer technology and can replicate the properties, functions, and behavior of the real object. In practice, a computer-aided model enables the analysis, planning, and optimization of processes or structures without directly interfering with the physical original. Various mathematical models for computer-aided models include differential equations, linear and nonlinear optimization models, stochastic models, neural networks, and/or agent-based models.

Repair scenarios can refer to theoretical repair planning processes, i.e., conceptual strategies and steps developed in advance of an actual repair in order to carry out the repair efficiently and effectively. These scenarios may consider various potential problems (e.g., external influences such as mechanical forces) and their solutions, based on the available information about the component and the machine.

A computer-aided model can be assigned to a component to be maintained using a variety of technologies and methods that significantly improve the efficiency and precision of maintenance work. A common approach is to use barcode or RFID scanning, whereby each component is assigned a unique code that calls up the corresponding digital model in the system when scanned. Alternatively, unique serial numbers can be used, which are stored in a database and serve as keys to identify the matching model. With advancing technology, sensors and IoT devices can also be used to continuously collect data from components, helping to find the right model in the system. Another innovative approach is image recognition, for example, in which cameras and specialized software can automatically recognize the component and assign the appropriate digital image. In cases where automated systems are not available, technicians can enter the identification data manually to establish the connection. Finally, integrated software solutions offer comprehensive databases that can automatically select the right model based on specific parameters such as size, shape, or function.

The actual condition of a component to be maintained can describe the current condition or present condition of the component at a specific point in time. This condition can include all relevant features and characteristics of the component that are important for assessing its functionality and maintenance requirements. This can include, for example, physical wear and tear, damage, material fatigue, and technical parameters such as temperature, pressure, or vibrations that are influenced by the operation of the component.

When adjusting the computer-aided model to the recorded actual condition, geometric adjustments can be made if the inspection or diagnosis reveals that a component is deformed or worn. The computer-aided (digital) model can be modified accordingly to reflect these changes. Material properties can also be updated if aging or environmental influences have changed the strength or elasticity of the material. Surface properties such as rough or corroded areas can also be represented in the model to facilitate friction or wear simulations. Structural defects such as cracks can be inserted into the model to analyze the integrity of the component and determine repair scenarios. In addition, functional parameters such as temperature, pressure, or vibration that the component experiences under real operating conditions can be adjusted to predict future problems. Furthermore, changes at connection points, such as play or loosening, can be represented in the model in order to optimize assembly strategies (i.e., repair scenarios). These adjustments enable the computer-aided model to potentially become a precise virtual representation of the actual condition of the physical component, which can form the basis for the repair process.

Repair measures may refer to actual physical activities, i.e., concrete, practical steps taken to restore a defective or worn component of the agricultural machine to a functional condition. This includes, for example, dismantling, cleaning, and/or repairing defects. A repair measure may involve at least partial implementation or practical application of the (theoretical) repair scenarios. Repair measures can be understood as maintenance or maintenance measures.

One advantage of the method may be that the performance and service life of the agricultural machine is maintained or improved in order to ensure smooth agricultural operations.

It is also possible to determine a large number of repair scenarios cost-effectively and computationally efficiently using computer systems (e.g., cloud systems) in order to derive a suitable repair measure from the repair scenarios. This means that a customized repair measure (or overhaul) can be ascertained for the component to be maintained. Maintenance of the components to be maintained can be crucial in preventing breakdowns and ensuring the efficiency and safety of the entire machine. Another advantage is the minimization of repair time for agricultural machinery.

In another aspect, the actual condition of the component to be maintained can be recorded by performing a guided diagnosis. The guided diagnosis can include, in one step, recording user input to describe the defects in the agricultural machine or the component to be maintained.

Furthermore, the guided diagnosis may comprise, in a further step, navigating through an interactive decision tree based on the user inputs and the computer-aided model assigned to the component to be maintained. Specific tests or inspections may be suggested as an option for further fault diagnosis. In a further step, the guided diagnosis can include recording the actual condition of the component to be maintained. The actual condition can be recorded by summarizing the test results.

Guided diagnostics can be a structured process for troubleshooting and repairing defects, in which technicians or users are guided through a series of predefined steps or questions in order to systematically identify the cause of a problem or defect in the component to be maintained. Guided diagnostics typically use software or instructions to standardize the diagnostic process and make it more efficient.

The interactive decision tree can be a visual and/or structured tool used for decision-making by presenting different options and their possible consequences. The interactive decision tree allows operators to navigate through a series of questions or decisions, for example, with each selection leading to a specific path that outlines further steps or recommendations based on the decisions made. Interactive may mean two-way communication or action between the user and the system (e.g., a repair assistant), in which both parties can respond to and influence each other. Various mathematical models for decision trees include, for example, the CART algorithm (Classification and Regression Trees), the ID3 algorithm (Iterative Dichotomiser 3), the C4.5 algorithm, and the random forest approach.

One advantage of guided diagnostics can be that the actual condition of the component to be maintained can be determined with particular precision. Guided diagnostics can help save time, minimize faults, and ensure consistency in the diagnostic process. Even less experienced users can work effectively, as they may be guided through a (standardized) process. Guided diagnostics can help optimize maintenance strategies and lead to cost savings by avoiding unnecessary repairs. Overall, guided diagnostics can increase the reliability and availability of machines.

In another aspect, a simulated repair scenario for the agricultural machine can be determined by simulating various measures using computer-aided models. Simulation can involve creating a virtual scenario in a computer-aided model in a single step. The virtual scenario can reflect the current configuration of the agricultural machine. Simulation can include ascertaining simulation results in a further step. The simulation results can be recorded by implementing a repair scenario and performing stress and functional analyses within the virtual scenario. In a further step, the simulation may include generating a report on the simulation results. The report may contain detailed information on the analyses performed, the expected performance improvements, and potential risks of the repair scenario.

The current configuration of the agricultural machine may include, for example, the specific equipment, settings, and software present on the machine at a given point in time, including attachments, technical settings, and electronic systems.

Simulation can enable potential repair measures to be tested virtually before physical interventions are carried out, reducing the risk of wrong decisions and costly mistakes. The quality of maintenance could thus be improved.

In another aspect, the method may include arranging for the repair measure to be carried out on the agricultural machine. The repair measure may include, in particular, the replacement of the component to be maintained with an identical new part, a similar component, a refurbished component, or an updated component.

Arranging the repair measures can be automated, thereby increasing flexibility. It is possible that the most suitable and cost-effective solution will be chosen as a repair measure, depending on availability and budget. This approach can increase the speed of restoring agricultural machinery to operational readiness, as repair measures are clearly defined and planned in advance.

In another aspect, the repair scenarios can be determined using the computer-aided model by defining a plurality of repair steps, ascertaining different sequences for the repair steps, and assigning a sequence of repair steps to each repair scenario.

A repair step can refer to a specific, defined action or measure that is carried out as part of a repair. A repair step can be, for example, the assembly, disassembly, or cleaning of a specific component of the agricultural machine.

In another aspect, the repair measure can be ascertained by prioritizing the repair scenarios. Prioritization can be ascertained based on cost, time, and/or energy expenditure.

Prioritization can refer to the process of arranging or evaluating tasks, projects, or goals according to their importance or urgency in order to use resources and time effectively. The goal of prioritization may be, for example, to ensure that the most important or urgent tasks are handled first in order to achieve the greatest benefit or the most effective results. Prioritization methods can range from simple to-do lists to more complex techniques such as the Eisenhower Matrix or the MOSCOW method, which can help categorize and evaluate tasks. Prioritization can make the method more time efficient.

In another aspect, the computer-aided model may comprise a three-dimensional model of the component to be maintained. The computer-aided model can represent a geometric structure and/or material properties, wherein the geometric structure is optionally derived from the recorded actual condition of the component to be maintained.

The geometric structure of a component to be maintained can refer to the physical shape, design, and spatial arrangement of its components. This may include specific dimensions such as length, width, height, diameter, angle, and other geometric features that define the shape and volume of the component. The material properties can describe the physical and chemical properties of the material from which the component is made. This can include, for example, strength, hardness, heat resistance, or elasticity.

In another aspect, providing the computer-aided model may include providing a general model for the component to be maintained in one step. In a further step, the provision of the computer-aided model may include the recording of information about the component to be maintained. The information may optionally include historical data on previous maintenance and repairs of the component to be maintained. In a further step, the provision of the computer-aided model may include adjusting the general model based on information about the component to be maintained. The general model can be adjusted so that the computer-aided model is derived.

In another aspect, ascertaining the repair measure in one step may include an analysis of repair scenarios. The repair scenarios can be analyzed by identifying and evaluating various repair scenarios based on the actual condition of the component to be maintained and/or the available resources. In a further step, ascertaining the repair measure may involve selecting an optimal repair scenario by weighing up the costs, time, and energy required for the measures. In a further step, ascertaining the repair measure may include ascertaining repair measures from the optimal repair scenario by deriving repair steps from the optimal repair scenario.

Another aspect relates to a method for performing a guided repair of a component to be maintained based on a repair measure ascertained according to one of the preceding aspects. The method may include providing detailed repair instructions describing specific steps and necessary tools in a single step. In a further step, the method may include providing an agricultural repair assistant that guides the operator through the repair process in real time by providing visual and audible cues. In a further step, the method may include monitoring the repair progress by means of sensors and/or feedback systems.

Another aspect relates to a data processing system for repairs to an agricultural machine, comprising a processor adjusted and/or configured to perform the method according to one of the preceding aspects.

Another aspect relates to an agricultural repair assistant with a data processing system according to one of the preceding aspects.

The repair assistant provides valuable support to operators and technicians during maintenance of agricultural machinery. The agricultural repair assistant can automate the repair process and help repair agricultural machinery more efficiently and accurately. It is possible that the repair assistant can be installed on mobile devices. This can lead to improved maintenance efficiency, reduced downtime, and optimal use of agricultural machinery.

It is understood that the features mentioned above and those to be explained below can be used not only in the combinations specified, but also in other combinations or individually, without departing from the scope of the present invention.

It is apparent to those skilled in the art that the methods presented can be implemented or stored in the form of instructions in software or on a computer program product, wherein stored instructions enable the steps according to the method to be carried out when a corresponding data processing machine is controlled by the software. In other words, it is possible that the methods are computer-implemented methods. Embodiments therefore also relate to a storage medium with software stored thereon that is designed to perform the methods described when the software is executed on a data processing device.

### BRIEF DESCRIPTION OF THE DRAWINGS

Further advantages and features result from the following embodiments, some of which refer to the figures. The figures do not always show the designs to scale. The dimensions of the various features may be enlarged or reduced for clarity of description. For this purpose, the figures are at least partially schematized.

FIG. 1 shows a schematic representation of a computer-implemented method for repairing an agricultural machine according to one embodiment; and

FIG. 2 shows a schematic representation of a repair assistant with a data processing system for repairs to an agricultural machine according to one embodiment.

The following description refers to the accompanying figures, which form part of the disclosure and illustrate certain aspects and embodiments in which the present disclosure may be understood. Identical reference symbols refer to identical or at least functionally or structurally similar features.

### DETAILED DESCRIPTION

In general, disclosure of a described method also applies to a corresponding device for carrying out the method or a corresponding system comprising one or more devices, and vice versa. For example, if a specific method step is described, a corresponding device may include a feature for performing the described method step, even if this feature is not explicitly described or shown in the figure. If, on the other hand, a specific device is described on the basis of functional units, a corresponding method may include one or more steps for performing the described functionality, even if these steps are not explicitly described or shown in the figures. Similarly, a system may include corresponding device features or characteristics for performing a specific method step. The features of the various exemplary aspects and embodiments described above or below may be combined, unless expressly stated otherwise.

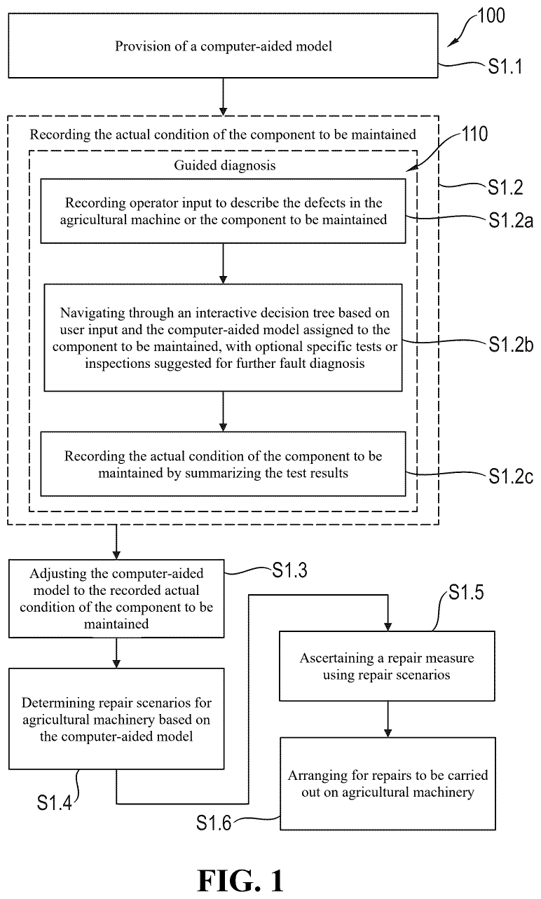

FIG. 1 shows a schematic representation of a computer-implemented method 100 for repairing an agricultural machine according to one embodiment.

The agricultural machine not shown here comprises a component to be maintained, i.e., a component that requires inspection, care, or repair (i.e., servicing) to ensure that the agricultural machine is functional and efficient.

In a first step S1.1, the method 100 may comprise providing a computer-aided model. The computer-aided model is assigned to the component to be maintained, for example.

In a further step S1.2, the method 100 comprises recording an actual condition of the component to be maintained. Recording the actual condition of the component to be maintained may involve further sub-steps. The actual condition of the component to be maintained can be recorded in particular by performing a guided diagnosis 110.

The guided diagnosis 110 may comprise, in step S1.2a, recording an operator input describing the defects of the agricultural machine or the component to be maintained. In a further step S1.2b, guided diagnosis 110 may comprise navigating through an interactive decision tree based on the user inputs and the computer-aided model assigned to the component to be maintained. Specific tests or inspections may be suggested as an option for further fault diagnosis.

For example, in guided diagnosis 110, an operator may be instructed to start by checking whether the component to be maintained shows any obvious physical damage; if so, a physical inspection is recommended. Optical methods can also be used for this purpose, i.e., an image of the component to be maintained can be recorded and physical damage detected using computer algorithms. If no damage is visible, it can be assessed whether the component is not functioning as expected. In the event of malfunctions without physical damage, further analysis is carried out to determine whether the system displays fault messages, which are then handled in accordance with the troubleshooting protocol. If there are no fault messages, it is examined, for example, whether any recent changes have been made to the software or hardware that may need to be reversed or updated. If all these steps fail to provide a solution, specific tests may be suggested, such as electrical, mechanical, or sensory tests, to determine the cause of the malfunction more precisely. Based on the results of these tests, further measures can be taken or an expert consulted.

In a further step S1.2c, the guided diagnosis 110 can record the actual condition of the component to be maintained by summarizing the test results.

In a further step S1.3, the method 100 comprises adjusting the computer-aided model to the recorded actual condition of the component to be maintained. For example, the component to be maintained may show signs of wear or cracks. The computer-aided model can be adjusted in such a way that wear and tear or cracks in the model are represented using physical, mathematical methods.

In a further step S1.4, the method 100 comprises determining repair scenarios for the agricultural machine based on the computer-aided model. It is possible to determine a large number of repair scenarios in a cost-effective and computationally efficient manner, for example using a cloud system, in order to derive a suitable repair measure from the repair scenarios.

In a further step S1.5, the method 100 comprises ascertaining a repair measure using the repair scenarios. This means that a customized repair measure (or overhaul) can be ascertained for the component to be maintained.

In a further step S1.6, the method 100 comprises arranging for the repair measure to be carried out on the agricultural machine. The repair measure may include, in particular, the replacement of the component to be maintained with an identical new part, a similar component, a refurbished component, or an updated component.

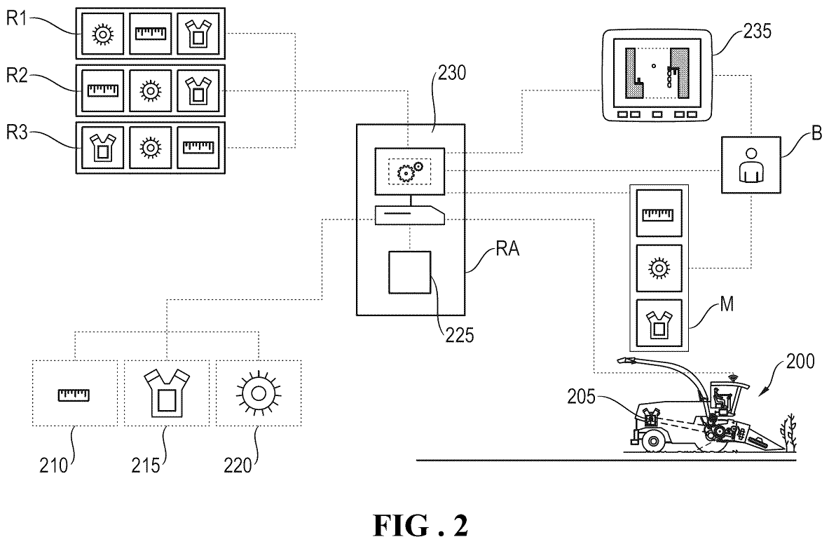

FIG. 2 shows a schematic representation of a repair assistant RA with a data processing system 230 for repairs to an agricultural machine 200 according to one embodiment.

In this example, the agricultural machine 200 is a forage harvester designed for harvesting crops. The agricultural machine 200 has the component 205 to be maintained, which in this example is an engine part.

The data processing system 230 for repairs comprises a processor 225 that is adjusted and/or configured to execute the method 100 according to any of the preceding aspects. The repair assistant RA also comprises an input device 235 for operator input to describe the defects of the agricultural machine 200 or the component 205 to be maintained. The operator input is usually made by an operator B, who may be a technician or a driver of the agricultural machine 200. The actual condition of the component 205 to be maintained is recorded here by operator B performing a guided diagnosis 110 using the input device 235. To do this, operator B can, for example, record an image of the component 205 to be maintained. An image processing algorithm (e.g., segmentation) may be used to ascertain the actual condition based on the image, wherein damage such as cracks or wear may be detected.

The computer-aided model can be provided on a storage medium of the repair assistant RA. Once the actual condition of the component 205 to be maintained has been recorded, the repair assistant RA can adjust the computer-aided model to the actual condition of the component 205 to be maintained. Finally, the repair measures for repairing the agricultural machine 200 or the component 205 to be maintained can be ascertained.

For this purpose, the repair assistant RA or data processing system 230 may be set up to perform further steps of the previously described method 100, wherein method 100 may comprise a computer-aided simulation. For example, one or more simulated repair scenarios R1, R2, and R3 for the agricultural machine 200 can be determined by simulating various measures using the computer-aided models. In other words, the simulation can assist in selecting a suitable repair scenario R1, R2, or R3 and, based on the suitable repair scenario R1, R2, or R3, derive a repair measure that ensures particularly efficient repair of the agricultural machine 200.

A large number of repair steps 210, 215, and 220 can be stored in the repair assistant RA or in a database. A repair scenario R1, R2, or R3 may comprise one or more repair steps 210, 215, or 220. A first repair step 210 may be, for example, to calibrate the engine control unit. A second repair step 215 may be, for example, replacement of an engine component. A third repair step 220 may be, for example, the assembly or fixing of a motor component.

Repair scenarios R1, R2, and R3 are determined using the computer-aided model by defining a plurality of repair steps 210, 215, and 220, ascertaining different sequences for repair steps 210, 215, and 220, and assigning a sequence of repair steps 210, 215, and 220 to each repair scenario R1, R2, and R3. For example, an initial repair scenario R1 provides for first calibrating the engine control unit (repair step 220), then replacing an engine component (repair step 210), and finally installing or fixing an engine component (repair step 215). Similarly, the other repair scenarios R2 and R3 may provide for different sequences for repair steps 210, 215, and 220.

Simulation may further comprise creating a virtual scenario in the computer-aided model in one step, wherein the virtual scenario reflects the current configuration of the agricultural machine 200. The current configuration of the agricultural machine may include, for example, specific equipment (e.g., the type of attachment). The virtual scenario can also depict the environment (e.g., workshop) and/or external influences on the agricultural machine 200. The computer-aided model may comprise a three-dimensional model of the component 205 to be maintained, which depicts a geometric structure and/or material properties, wherein the geometric structure is optionally derived from the recorded actual condition of the component 205 to be maintained.

In a further step, simulation can include ascertaining simulation results by implementing repair measures R1, R2, or R3 and performing stress and functional analyses, e.g., based on a finite element method, within the virtual scenario.

Simulation may further comprise generating a report on the simulation results in one step, which contains detailed information on the analyses performed, the expected performance improvements, and potential risks of the repair measures.

Using repair scenarios R1, R2, or R3, a repair measure M can be ascertained, which is then transmitted to or displayed to the operator B, for example. In this case, repair measure M was derived from repair scenario R2, for example. This may mean that, as a repair measure M, the repair steps specified in repair scenario R2 are to be applied to the agricultural machine 200 automatically or manually. It is also possible that the repair assistant RA initiates repair measure M on agricultural machine 200. For this purpose, the repair assistant RA may have additional devices, such as a mechanical gripper arm, which perform the repair measures M, such as assembly, disassembly, or cleaning.

The reference list is shown in the Table below:

Reference List

| | |
|---|---|
| 100 | computer-implemented method |
| 110 | guided diagnosis |
| 200 | agricultural machine |
| 205 | component to be maintained |
| 210 | first repair step |
| 215 | second repair step |
| 220 | third repair step |
| 225 | processor |
| 230 | data processing system |
| 235 | input device |
| RA | repair assistant |
| R1 | first repair scenario |
| R2 | second repair scenario |
| R3 | third repair scenario |
| M | repair measure |
| B | operator |
| S1.1 | provision of a computer-aided model |
| S1.2 | recording the actual condition of the component to be maintained |
| S1.2a | recording operator input to describe the defects in the agricultural |
| | machine or the component to be maintained |
| S1.2b | navigation through an interactive decision tree based on user |
| | input and the computer-aided model assigned to the component |
| | to be maintained |
| S1.2c | recording the actual condition of the component to be maintained |
| S1.3 | adjusting the computer-aided model to the recorded |
| | actual condition of the component to be maintained |
| S1.4 | determining repair scenarios for agricultural machinery |
| | based on the computer-aided model |
| S1.5 | ascertaining a repair measure using repair scenarios |
| S1.6 | arranging for repairs to be carried out on agricultural machinery |

What is claimed is:

1. A computer-implemented method for repairing an agricultural machine, wherein the agricultural machine comprises a component to be maintained, the method comprising:
providing (S1.1) a computer-aided model, wherein the computer-aided model is associated with the component to be maintained;
recording (S1.2) the actual condition of the component to be maintained and adjusting (S1.3) the computer-aided model to the recorded actual condition of the component to be maintained;
determining (S1.4) repair scenarios (R1, R2, R3) for the agricultural machine based on the computer-aided model; and
ascertaining (S1.5) a repair measure (M) using the repair scenarios (R1, R2, R3).

2. The method according to claim 1, the method comprising:
recording the actual condition of the component to be maintained by performing a guided diagnosis,
the guided diagnosis comprising:
recording (1.2a) user input describing the defects of the agricultural machine or the component to be maintained;
navigating (1.2b) through an interactive decision tree based on the user inputs and the computer-aided model assigned to the component to be maintained, wherein specific tests or inspections are optionally suggested for further fault diagnosis; and
recording (1.2c) the actual condition of the component to be maintained by summarizing the test results.

3. The method according to claim 1, the method comprising:
determining a simulated repair scenario for the agricultural machine by simulating various measures using computer-aided models,
wherein simulating comprises:
creating a virtual scenario in the computer-aided model, wherein the virtual scenario reflects the current configuration of the agricultural machine;
ascertaining simulation results by implementing a repair scenario (R1, R2, R3) and performing stress and functional analyses within the virtual scenario; and
generating a report on the simulation results, which contains detailed information on the analyses performed, expected performance improvements, and potential risks of the repair scenario (R1, R2, R3).

4. The method according to claim 1, further comprising arranging (S1.6) the repair measure (M) on the agricultural machine, wherein the repair measure (M) comprises replacing the component to be maintained with an identical new part, a similar component, a refurbished component, or an updated component.

5. The method according to claim 1 wherein the repair scenarios (R1, R2, R3) are determined by means of the computer-aided model by specifying a plurality of repair steps, ascertaining different sequences for the repair steps, and assigning a sequence of repair steps to each repair scenario (R1, R2, R3).

6. The method according to claim 1, wherein the repair measure is ascertained by prioritizing the repair scenarios (R1, R2, R3), wherein the prioritization is ascertained on the basis of the costs, the time, and/or the energy expenditure.

7. The method according to claim 1, wherein the computer-aided model comprises a three-dimensional model of the component to be maintained, which depicts a geometric structure and/or material properties, wherein the geometric structure is optionally derived from the recorded actual condition of the component to be maintained.

8. The method according to claim 1, wherein providing the computer-aided model comprises:
providing a general model for the component to be maintained;
recording information about the component to be maintained, wherein the information optionally includes historical data of previous maintenance and repairs of the component to be maintained; and
adjusting the general model based on information about the component to be maintained so that the computer-aided model is derived.

9. The method according to claim 1, wherein ascertaining the repair measure (M) comprises:
analysis of repair scenarios (R1, R2, R3) in which the various repair scenarios (R1, R2, R3) are identified and assessed based on the actual condition of the component to be maintained and/or the available resources;
selecting an optimal repair scenario (R1, R2, R3) by weighing up the costs, time, and energy required for the repair measures; and
ascertaining repair measures (R1, R2, R3) from the optimal repair scenario (R1, R2, R3) by deriving repair steps from the optimal repair scenario (R1, R2, R3).

10. A method for performing a guided repair of a component to be maintained based on an ascertained repair measure (M) according to claim 1, comprising:
providing detailed repair instructions (M) that describe specific steps and required tools;
providing an agricultural repair assistant that guides the operator through the repair process in real time by providing visual and audible cues; and
monitoring repair progress using sensors and/or feedback systems.

11. A data processing system for repairs of an agricultural machine, comprising a processor adjusted and/or configured to execute the method according to claim 1.

12. An agricultural repair assistant (RA) comprising a data processing system according to claim 11.
